(19) United States
(12) Patent Application Publication
(10) Pub. No.: US 2013/0276859 A1
(43) Pub. Date: Oct. 24, 2013

(54) SOLAR CELL AND SOLAR CELL MODULE

(71) Applicant: Sanyo Electric Co., Ltd., Moriguchi City (JP)

(72) Inventor: Takahiro Mishima, Kobe-shi (JP)

(21) Appl. No.: 13/927,147

(22) Filed: Jun. 26, 2013

Related U.S. Application Data
(63) Continuation of application No. PCT/JP2011/079157, filed on Dec. 16, 2011.

(30) Foreign Application Priority Data
Dec. 28, 2010 (JP) 2010-291580

(51) Int. Cl. H01L 31/0224

(52) U.S. Cl. CPC H01L 31/022425
USPC 136/244; 136/256

(57) ABSTRACT

A solar cell having improved photoelectric conversion efficiency and a solar cell module are provided. A first electrode (21) has a plurality of first electrode portions (21a) and second electrode portions (21b). Each of the plurality of first electrode portions (21a) is provided so as to extend in a first direction (y). The plurality of first electrode portions (21a) is arranged in a second direction (x), which is perpendicular to the first direction (y). Each of the plurality of first electrode portions (21a) has a linear shape. The plurality of first electrode portions (21a) is connected electrically to a second electrode portion (21b). At least a part of the second electrode portion (22b) is thicker than the first electrode portions (21a).

### CROSS-REFERENCE TO RELATED APPLICATIONS

This is a continuation of International Application PCT/JP2011/079157, with an international filing date of Dec. 16, 2011, filed by applicant, the disclosure of which is hereby incorporated by reference in its entirety.

### FIELD OF THE INVENTION

The present invention relates to a solar cell and a solar cell module incorporating the solar cell.

### BACKGROUND ART

A solar cell has a photoelectric conversion portion for generating carriers such as electrons and holes from received light, and electrodes for collecting the carriers generated by the photoelectric conversion unit. The electrodes, as described in Patent Document 1, are a pair of comb-shaped electrodes which are inserted into each other.

### PRIOR ART DOCUMENTS

### Patent Documents

Patent Document 1: Laid-Open Patent Publication No. 2010-80887

### SUMMARY OF THE INVENTION

### Problem Solved by the Invention

There is growing demand for greater photoelectric conversion efficiency in solar cells.

In light of this situation, the purpose of the present invention is to provide a solar cell and solar cell module with improved photoelectric conversion efficiency.

### Means of Solving the Problem

The solar cell of the present invention includes a photoelectric conversion portion, a first electrode, and a second electrode. The photoelectric conversion portion has a first and second main surface. The first and second main surfaces include a p-type surface and an n-type surface. The first electrode is connected electrically to one of the p-type surface and the n-type surface. The first electrode is arranged at least partially on the first main surface. The second electrode is connected electrically to the other of the p-type surface and the n-type surface. The second electrode is arranged at least partially on the first main surface. The first electrode has a plurality of first electrode portions and a second electrode portion. Each of the plurality of first electrode portions is provided so as to extend in a first direction. Each of the plurality of first electrode portions is arranged in a second direction, which is perpendicular to the first direction. Each of the plurality of first electrode portions is linear. The plurality of first electrode portions is connected electrically to the second electrode portion. At least a part of the second electrode portion is thicker than the first electrode portions.

The solar cell module of the present invention has a plurality of solar cells and wiring material. The wiring material electrically connects adjacent solar cells to each other. The solar cell includes a photoelectric conversion portion, a first electrode, and a second electrode. The photoelectric conversion portion has a first and second main surface. The first and second main surfaces include a p-type surface and an n-type surface. The first electrode is connected electrically to one of the p-type surface and the n-type surface. The first electrode is arranged at least partially on the first main surface. The second electrode is connected electrically to the other of the p-type surface and the n-type surface. The second electrode is arranged at least partially on the first main surface. The first electrode has a plurality of first electrode portions and second electrode portions. Each of the plurality of first electrode portions is provided so as to extend in a first direction. Each of the plurality of first electrode portions is arranged in a second direction, which is perpendicular to the first direction. Each of the plurality of first electrode portions is linear. The plurality of first electrode portions is connected electrically to the second electrode portion. At least a part of the second electrode portion is thicker than the first electrode portions.

### Effect of the Invention

The present invention is able to provide a solar cell and solar cell module with improved photoelectric conversion efficiency.

### BRIEF DESCRIPTION OF THE DRAWINGS

FIG. 1 is a schematic cross-sectional view of the solar cell module in a first embodiment.

FIG. 2 is a schematic plan view of the back surface of the solar cell in the first embodiment.

FIG. 3 is a schematic cross-sectional view from line III-III in FIG. 2.

FIG. 4 is a schematic cross-sectional view from line IV-IV in FIG. 2.

FIG. 5 is a schematic rear view of the solar cell string in the first embodiment.

FIG. 6 is a schematic plan view of the back surface of the solar cell in a prior art example.

FIG. 7 is a schematic cross-sectional view from line VII-VII in FIG. 6.

FIG. 8 is a schematic cross-sectional view from line VIII-VIII in FIG. 6.

FIG. 9 is a schematic cross-sectional view of the solar cell in a second embodiment.

FIG. 10 is a schematic cross-sectional view of the solar cell in a third embodiment.

FIG. 11 is a schematic plan view of the back surface of the solar cell in a fourth embodiment.

FIG. 12 is a schematic plan view of the back surface of the solar cell in a fifth embodiment.

FIG. 13 is a schematic cross-sectional view from line XIII-XIII in FIG. 12.

FIG. 14 is a schematic plan view of the back surface of the solar cell in a sixth embodiment.

FIG. 15 is a schematic plan view of the back surface of the solar cell in a seventh embodiment.

### DETAILED DESCRIPTION

The following is an explanation of preferred embodiments of the present invention. The following embodiments are merely illustrative. The present invention is not limited to these embodiments.

Further, in each of the drawings referenced in the embodiments, members having substantially the same function are denoted by the same symbols.

The drawings referenced in the embodiments are also depicted schematically. The dimensional ratios of the objects depicted in the drawings may differ from those of the actual objects. The dimensional ratios of objects may also vary between drawings. The specific dimensional ratios of the objects should be determined with reference to the following explanation.

### 1st Embodiment

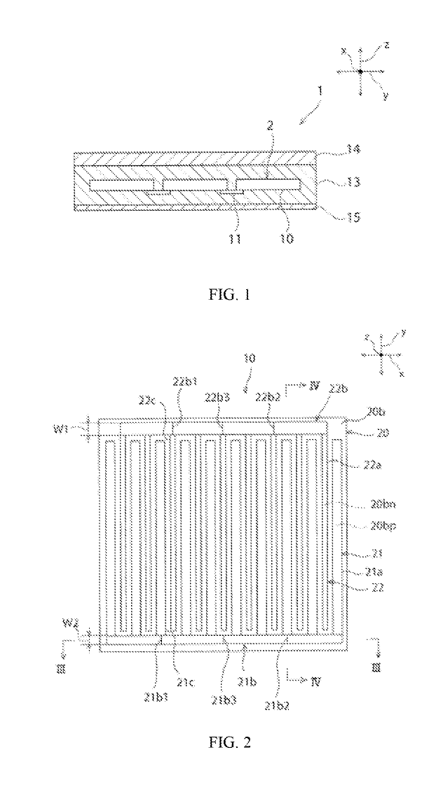

FIG. 1 is a schematic cross-sectional view of the solar cell module 1 in a first embodiment. The solar cell module 1 includes a solar cell string 2. The solar cell string 2 is a plurality of solar cells 10 arranged in the y direction.

The solar cells 10 are connected electrically via wiring material 11. More specifically, the solar cells 10 are connected electrically in series or in parallel by electrically connecting adjacent solar cells 10 to each other via wiring material 11.

The wiring material 11 and solar cells 10 are bonded to each other using a bonding agent. The bonding agent can be solder or a resin adhesive. When the bonding agent is a resin adhesive, the resin adhesive may have insulating properties or anisotropic conductive properties.

A first protective member 14 and a second protective member 15 are arranged on the light-receiving surface and the back surface of each solar cell 10.

The first protective member 14 is arranged on the light-receiving surface of each solar cell 10. The first protective member 14 can be a glass or transparent resin substrate or sheet.

The second protective member 15 is arranged on the back surface of each solar cell 10. The second protective member 15 can be a metal foil such as aluminum foil interposed between sheets of resin film.

A sealing material 13 is provided between each solar cell 10 and its first protective member 14 and between each solar cell 10 and its second protective member 15.

There are no particular restrictions on the sealing material 13 or the material used in the first and second protective members 14, 15. The sealing material 13 can be formed using a resin with transparent properties, such as an ethylene-vinyl acetate (EVA) copolymer or polyvinyl butyral (PVB).

If necessary, a frame made of a metal such as Al (not shown) can be attached to the peripheral surface of a laminate comprising a first protective member 14, sealing material 13, a solar cell string 2, sealing material 13 and a second protective member 15.

Wiring material and a terminal box may be provided on the surface of the second protective member 15 to extract the output of the solar cell 10.

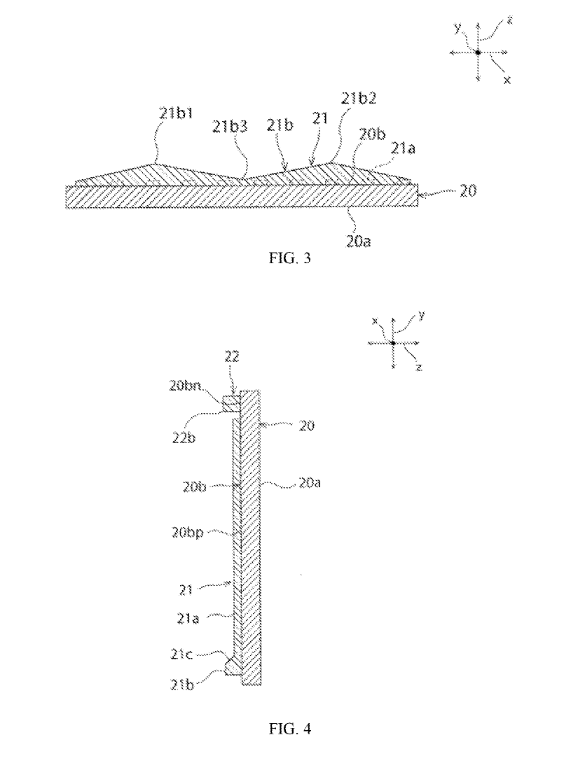

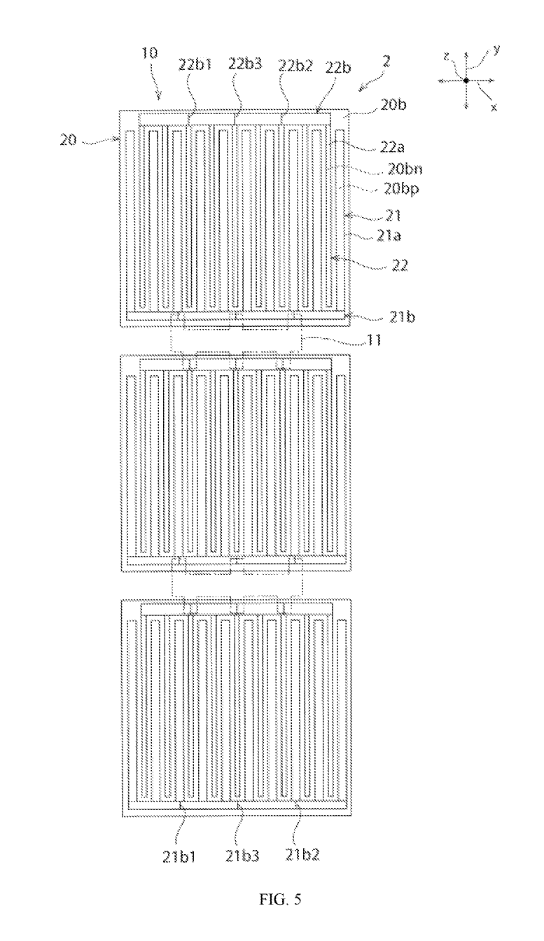

FIG. 2 is a schematic plan view of the back surface of the solar cell 10 in the present embodiment. FIG. 3 is a schematic cross-sectional view from line III-III in FIG. 2. FIG. 4 is a schematic cross-sectional view from line IV-IV in FIG. 2. The following is an explanation of the configuration of a solar cell 10 with reference to FIG. 2 through FIG. 4.

The solar cell 10 has a photoelectric conversion portion 20. The photoelectric conversion portion 20 generates carriers such as electrons and holes from received light. The photoelectric conversion portion 20 may have a crystalline semiconductor substrate and p-type and n-type amorphous semiconductor layers arranged on top of the crystalline semiconductor substrate. The photoelectric conversion portion 20 may also have a semiconductor substrate having an n-type dopant diffusion region and p-type dopant diffusion region exposed on the surface.

In the present embodiment, the photoelectric conversion portion 20 is configured so that a majority of carriers are electrons and a minority of carriers are holes.

There are no particular restrictions on the shape of the photoelectric conversion portion 20. The photoelectric conversion portion 20 can be, for example, rectangular. The photoelectric conversion portion 20 can also, for example, be rectangular with beveled corners.

The photoelectric conversion portion 20 has a light-receiving surface 20a and a back surface 20b. In the present embodiment, the solar cells 10 are back junctionsolar cells with a p-type surface 20bp and an n-type surface 20bn on the back surface 20b.

A p-side electrode 21 and an n-side electrode 22 are arranged on the back surface 20b. More specifically, the p-side electrode 21 is arranged on the p-type surface 20bp. The p-side electrode 21 is connected electrically to the p-type surface 20bp. The n-side electrode 22 is arranged on the n-type surface 20bn. The n-side electrode 22 is connected electrically to the n-type surface 20bn.

At least a part of the p-side electrode 21 and the n-side electrode 22 are arranged on the back surface 20b. The other part may be arranged on the light-receiving surface 20a.

The material in each of the p-side electrodes 21 and n-side electrodes 22 may be any conductive material. The p-side electrodes 21 and the n-side electrodes 22 may both be made of a metal such as silver, copper, aluminum, titanium, nickel or chrome, or an alloy of one or more of these metals. Each of the p-side electrodes 21 and n-side electrodes 22 may be made of a laminate having a plurality of conductive layers made, in turn of a metal or metal alloy.

There are no particular restrictions on the method used to form the p-side electrode 21 and n-side electrode 22. The p-side electrode 21 and n-side electrode 22 may be formed, for example, by applying and baking a conductive paste, or by using a sputtering method, vacuum evapuration method, inkjet method, dispenser method, screen printing method or plating method.

Each of the p-side electrodes 21 and n-side electrodes 22 may be comb-shaped. The p-side electrodes 21 and n-side electrodes 22 may be inserted between each other. In the present invention, both of the first and second electrodes do not have to be comb-shaped electrodes. For example, either the first or second electrodes may have a plurality of finger electrode portions. In other words, either the first electrode or the second electrode may be a so-called busbarless electrode.

The p-side electrode 21 has a plurality of finger electrode portions 21a and busbar portions 21b. Each of the finger electrode portions 21a is linear. Each of the finger electrode portions 21a also extends in the y direction. The finger electrode portions 21a are arranged in the x direction perpendicular to the y direction.

The thickness of each finger electrode portion 21a is constant. In other words, the thickness of each finger electrode portion 21a does not change in the y direction. Here, “constant thickness” means the difference between the maximum thickness and the average thickness, and the difference between the average thickness and the minimum thickness is less than 30% of the average thickness.

The finger electrode portions 21a are connected electrically to the busbar portions 21b. In the present embodiment, the busbar portions 21b are linear and extend in the x direction.

The width W2 of the busbar portions 21b extending in the y direction is constant in the x direction. Here, “constant width” means the difference between the maximum width and the average width, and the difference between the average width and the minimum width is less than 20% of the average width.

The n-side electrode 22 has a plurality of finger electrode portions 22a and busbar portions 22b. Each of the finger electrode portions 22a is linear. Each of the finger electrode portions 22a extends in the y direction. The finger electrode portions 22a are arranged in the x direction, which is perpendicular to the y direction. The finger electrode portions 21a and the finger electrode portions 22a are arranged so as to alternate with each other in the x direction.

The thickness of each of the finger electrode portions 22a is constant. In other words, the thickness of each of the finger electrode portions 22a does not change in the y direction.

The finger electrode portions 22a are connected electrically to the busbar portions 22b. In the present embodiment, the busbar portions 22b are linear and extend in the x direction.

The width W1 of the busbar portions 22b extending in the y direction is constant in the x direction.

In the present invention, at least a part of the busbar portions 21b, 22b is thicker than the finger electrode portions 21a, 22a. In this way, at least a part of the cross-sectional area of the busbar portions 21b, 22b is greater than the cross-sectional area of the finger electrode portions 21a, 22a.

More specifically, each of the busbar portions 21b, 22b has thicker parts and thinner parts which alternate in the x direction. The thickness of the thicker parts and thinner parts in each of the busbar portions 21b, 22b changes gradually.

In each of the busbar portions 21b, 22b, the thickness of the thickest parts 21b3, 22b3 is greater than the thickness of the finger electrode portions 21a, 22a. In this way, the electrical resistance of the thickest parts 21b3, 22b3 is less than the electrical resistance of the finger electrode portions 21a, 22a.

In each of the busbar portions 21b, 22b, the thickness of the thickest parts 21b1, 21b2, 22b1, 22b2 is preferably greater than the thickness of the finger electrode portions 21a, 22a, more preferably 1.5 times greater, and even more preferably 2.0 times greater than the thickness of the finger electrodes 21a, 22a.

There are two thickest parts 21b1, 21b2 and ten finger electrode portions 21a in the p-side electrode 21. In each busbar portion 21b, 22b, there is a thinnest part 21b3, 22b3 on both sides so that the thickest parts 21b1, 21b2, 22b1, 22b2 are linearly symmetrical with respect to the center. The thickness of the thickest parts 21b1, 21b2 is preferably greater than the following: (thickness of the finger electrode portion 21a)×10/4.

There are two thickest parts 22b1, 22b2 and nine finger electrode portions 22a in the n-side electrode 22. The thickness of the thickest parts 22b1, 22b2 is preferably greater than the following: (thickness of the finger electrode portion 22a)×9/4. In this way, collection loss can be minimized in the busbar portions 21b, 22b.

As shown in FIG. 4, the thicker busbar portions 21b, 22b and the thinner finger electrode portions 21a, 22a are connected by connector portions 21c, 22c which gradually increase in thickness towards the busbar portions 21b, 22b.

FIG. 5 is a schematic rear view of the solar cell string 2 in the first embodiment. Wiring material 11 is used to electrically connect thickest parts 21b1, 21b2, 22b1, 22b2. More specifically, the thickest parts 21b1, 21b2 of the busbar portion 21b of the p-side electrode 21 in the adjacent solar cell 10 on one side are connected electrically by wiring material 11 to the thickest parts 22b1, 22b2 of the busbar portion 22b of the n-side electrode 22 in the adjacent solar cell 10 on the other side. In this way, the thickness of the busbar portions 21b, 22b becomes smaller moving away from the connection with the wiring material 11.

The current collected from the finger electrode portions is concentrated in the busbar portions in the part connected to the wiring material. As a result, the current density tends to be higher in the busbar portions in the part connected to the wiring material. When the cross-sectional area of the busbar portion is small in the part connected to the wiring material and the electrical resistance is high, some of the electric power is converted to Joule heat in this part and collection loss increases. As a result, the photoelectric conversion efficiency declines.

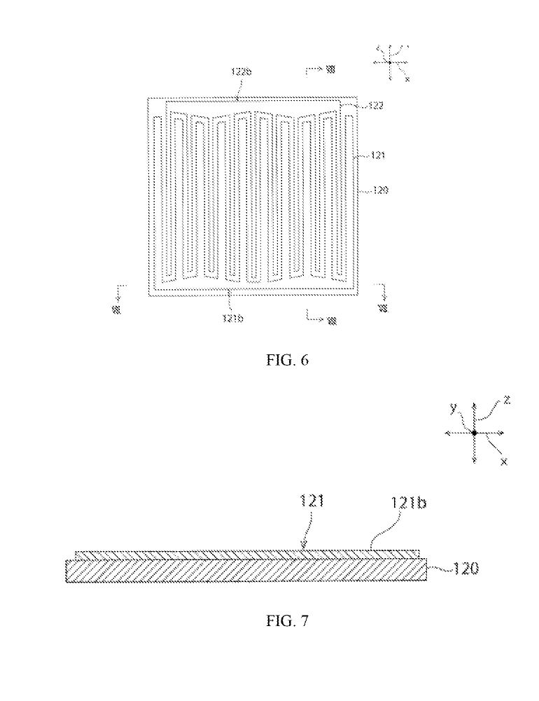

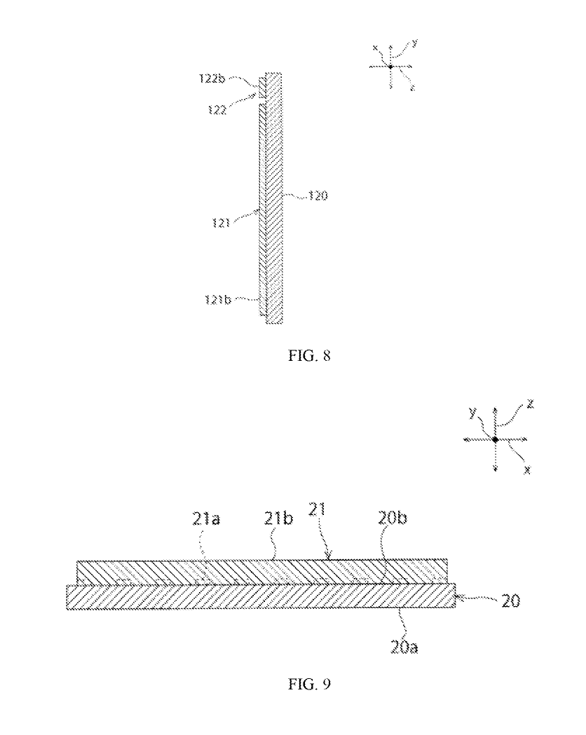

Increasing the cross-sectional area of the busbar portion by increasing the thickness of the busbar portion has been considered in order to address this problem. More specifically, as shown in FIG. 6 through FIG. 8, any decrease in the current collected in the busbar portion can be minimized by increasing the width of the part of the busbar portions 121b, 122b connected to the wiring material. However, when the width of the busbar portions 121b, 122b is increased, the electrons generated in the part of the photoelectric conversion portion 120 below the busbar portion 121b of the p-side electrode 121 have to travel a long distance before being collected by the n-side electrode 122. Also, the holes generated in the part of the photoelectric conversion portion 120 below the busbar portion 122b of the n-side electrode 122 have to travel a long distance before being collected by the p-side electrode 121. As a result, the recombination of carriers is more likely to occur. This leads to a decline in photoelectric conversion efficiency. Photoelectric conversion efficiency tends to decline greatly, even when a minority of carriers are likely to recombine.

However, in the present embodiment, at least a part of the busbar portions 21b, 22b is thicker than the finger electrode portions 21a, 22a. As a result, the cross-sectional area of at least a part of the busbar portions 21b, 22b is greater than the cross-sectional area of the finger electrode portions 21a, 22a. This suppresses any increase in the area taken up by the busbar portions 21b, 22b, and suppresses any decrease in the current collected by the busbar portions 21b, 22b. As a result, improved photoelectric conversion efficiency can be realized.

### 2nd Embodiment

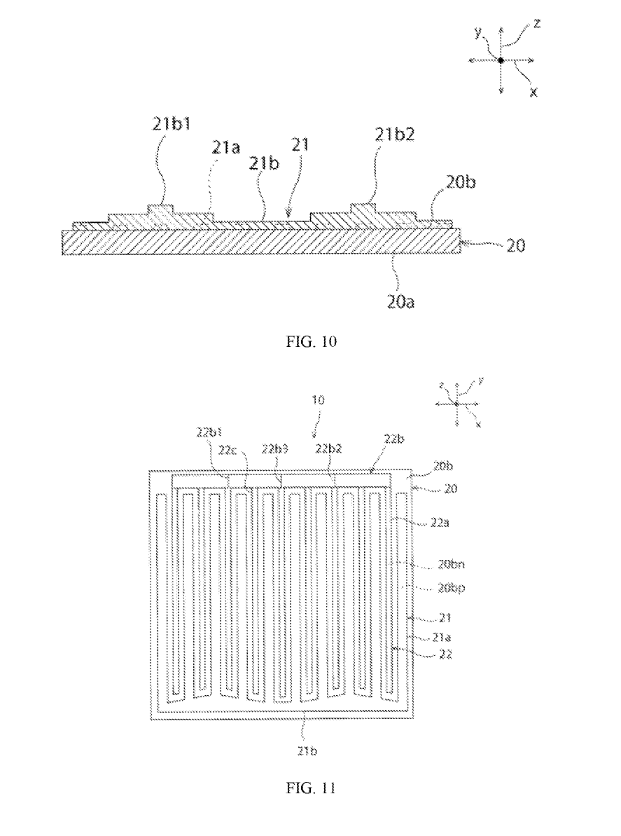

In order to suppress any decrease in the current collecting in the busbar portions, as shown in FIG. 9, the thickness of the busbar portions 21b, 22b can be made constant, and the busbar portions 21b, 22b can be made uniformly thicker than the finger electrode portions 21a, 22a. Also, as shown in FIG. 10, the thickness of the busbar portions 21b, 22b can gradually change.

However, when the busbar portions 21b, 22b are made uniformly thicker than the finger electrode portions 21a, 22a in the second embodiment shown in FIG. 9, the amount of electrode material needed to form the busbar portions 21b, 22b increases. This increases solar cell manufacturing costs. Therefore, increasing the thickness of only a part of the busbar portions 21b, 22b as in the first embodiment is preferred.

### 3rd Embodiment

When the thickness of the busbar portions 21b, 22b gradually changes as in the third embodiment shown in FIG. 10, less electrode material is needed to form the busbar portions 21b, 22b as in the first embodiment. However, when the thickness of the busbar portions 21b, 22b gradually changes, stress tends to concentrate in the parts where the thickness changes. This makes the busbar portions 21b, 22b more susceptible to coming off or being damaged. Therefore, increasing the thickness of only a part of the busbar portions 21b, 22b as in the first embodiment is preferred.

In the second and third embodiments shown in FIG. 9 and FIG. 10 and in the fourth through seventh embodiments, members having substantially the same function as those in the first embodiment are denoted by the same symbols, and further explanation has been omitted.

### 4th Embodiment

FIG. 11 is a schematic plan view of the back surface of the solar cell in a fourth embodiment.

In the first embodiment, the busbar portions 21b, 22b of both the p-side electrode 21 and the n-side electrode 22 have thick parts. However, the present invention is not restricted to this configuration. For example, a thick part may be provided in only the electrode collecting the majority of carriers (the n-side electrode 22 in the present invention) because the recombination of a majority of carriers has a greater impact on photoelectric conversion efficiency than the recombination of a minority of carriers. For example, when a thicker portion is provided in the busbar portions 22b of the n-side electrode 22, as shown in FIG. 11, any reduction in current collected by the busbar portions 22b is suppressed. When a thicker portion is provided in the busbar portions 21b of the p-side electrode 21, any reduction in current collected by the busbar portions 21b is suppressed.

Also, a part of the busbar portions 21b, 22b of at least one of the p-side electrode 21 and the n-side electrode 22 may be thicker and wider. Because the area taken up by the busbar portions is not increased, improved photoelectric conversion efficiency can be obtained.

### 5th Embodiment

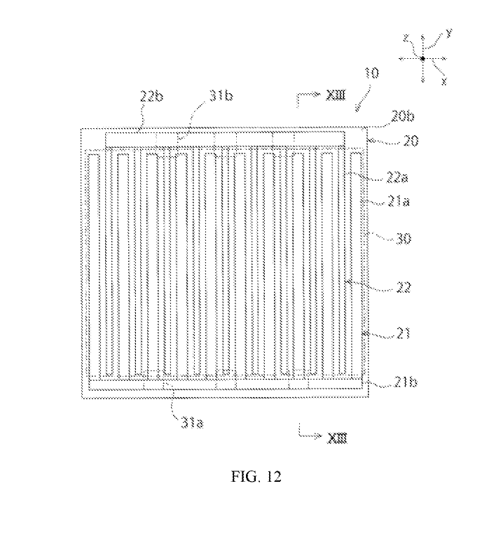

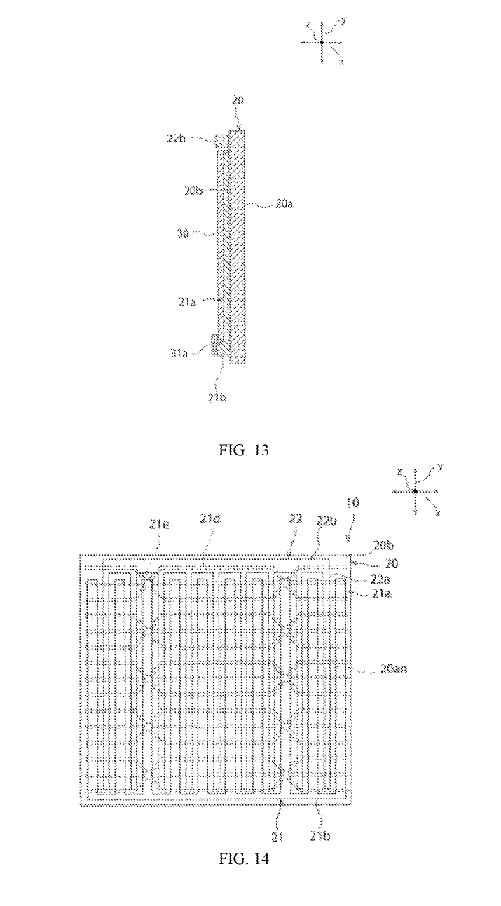

FIG. 12 is a schematic plan view of the back surface of the solar cell in a fifth embodiment. FIG. 13 is a schematic cross-sectional view from line XIII-XIII in FIG. 12. As shown in FIG. 12 and FIG. 13, an insulating film 30 is provided on the back surface 20b of the solar cell in the present embodiment to cover the finger electrode portions 21a, 22a. The electrode pads 31a, 31b formed in the thickest parts of 21b1, 21b2, 22b1, 22b2 of the busbar portions 21b, 22b become larger as they reach the top of the insulating film 30.

Because, as in the present embodiment, the electrode pads 31a, 31b are thicker when an insulating film 30 is formed, the electrical resistance can be reduced where the wiring material 11 connects to the solar cell 10.

### 6th Embodiment

FIG. 14 is a schematic plan view of the back surface of the solar cell in a sixth embodiment.

In the first embodiment, the solar cells 10 are back junctionsolar cells with a p-type surface 20bp and an n-type surface 20bn on the back surface 20b. However, the present invention is not restricted to this configuration.

In the present embodiment, the n-type surface 20bn is exposed on the back surface 20b, and the p-type surface 20bp is exposed on the light-receiving surface 20a. An electrode portion 21d is formed on the p-type surface 20bp of the light-receiving surface 20a. The electrode portion 21d is connected electrically to finger electrode portions 21a via a through-hole electrode 21e passing through the photoelectric conversion portion 20. In the solar cell of the present invention, only a part of the busbar portions 21b, 22b is thicker than the finger electrodes 21a, 22a. As a result, photoelectrical conversion efficiency improvements similar to those in the first embodiment can be realized.

### 7th Embodiment

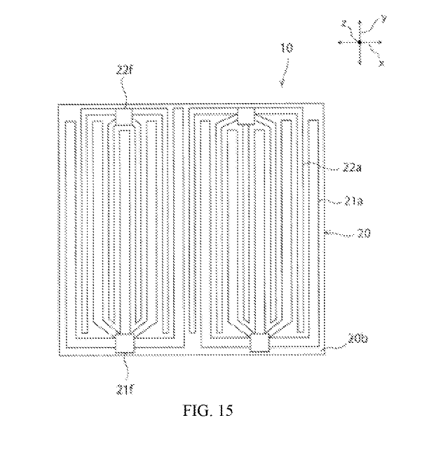

FIG. 15 is a schematic plan view of the back surface of the solar cell in a seventh embodiment.

In the first embodiment, the second and fourth electrode portions comprised linear busbar portions 21b, 22b. However, the present invention does not have to have linear second and fourth electrode portions.

For example, as shown in FIG. 15, electrode pads 21f, 22f may be provided as the second and fourth electrode portions, and the electrode pads 21f, 22f may be thicker than the finger electrode portions 21a, 22a. This decreases the area taken up by the electrode pads 21f, 22f. As a result, the present embodiment is able to realize improved photoelectric conversion efficiency.

### KEY TO THE DRAWINGS

1: solar cell module
2: solar cell string
10: solar cell
11: wiring material
20: photoelectric conversion portion
20a: light-receiving surface
20b: back surface
20bn: n-type surface
20bp: p-type surface
21: p-side electrode
22: n-side electrode
21a, 22a: finger electrode portion
21b, 22b: busbar portion
21f, 22f, 31a, 31b: electrode pads
30: insulating film

What is claimed is:

1. A solar cell comprising:
a photoelectric conversion portion having a first and second main surface including a p-type surface and an n-type surface,
a first electrode connected electrically to one of the p-type surface and the n-type surface and arranged at least partially on the first main surface, and
a second electrode connected electrically to the other of the p-type surface and the n-type surface and arranged at least partially on the first main surface;
the first electrode being provided so as to extend in a first direction, and have a plurality of first electrode portions arranged in a second direction perpendicular to the first direction, and a second electrode portion connected electrically to the plurality of first electrode portions; and
at least a part of the second electrode portion being thicker than the first electrode portions.

2. The solar cell according to claim 1, wherein at least the cross-sectional area of the second electrode portion is greater than the cross-sectional area of the first electrode portions.

3. The solar cell according to claim 1, wherein the first electrode is the electrode collecting the majority of carriers.

4. The solar cell according to claim 1, wherein the second electrode portion is linear, and
a relatively thick portion and a relatively thin portion extend in the second direction in the second electrode portion.

5. The solar cell according to claim 4, wherein the thickness gradually changed between the relatively thick portion and the relatively thin portion.

6. The solar cell according to claim 1, wherein the thickness of the second electrode portion is constant.

7. The solar cell according to claim 1, wherein the thickness of the first electrode portions is constant.

8. The solar cell according to claim 1,
wherein the second electrode has a plurality of linear third electrode portions of constant thickness provided so as to extend in the first direction between first electrode portions adjacent to each other in the second direction, and a fourth electrode portion connected electrically to the plurality of third electrode portions,
at least a part of the fourth electrode portion being thicker than the third electrode portions.

9. A solar cell module having a plurality of solar cells and wiring material electrically connecting adjacent solar cells to each other,
each solar cell comprising a photoelectric conversion portion having a first and second main surface including a p-type surface and an n-type surface, a first electrode connected electrically to one of the p-type surface and the n-type surface and arranged at least partially on the first main surface, and a second electrode connected electrically to the other of the p-type surface and the n-type surface and arranged at least partially on the first main surface;
the first electrode being provided so as to extend in a first direction, and have a plurality of first electrode portions arranged in a second direction perpendicular to the first direction, and a second electrode portion connected electrically to the plurality of first electrode portions; and
at least a part of the second electrode portion being thicker than the first electrode portions.

10. The solar cell module of claim 9, wherein the wiring material is connected electrically to a part of the second electrode portion having a thickness greater than the first electrode portions.

11. The solar cell module of claim 10, wherein the second electrode portion becomes thinner further away from the connection portion with the wiring material.

12. The solar cell module in claim 9, wherein the thickness of the first electrode portions is constant.
